(19) United States
(12) Patent Application Publication
(10) Pub. No.: US 2026/0129769 A1
(43) Pub. Date: May 7, 2026

(54) FEEDING DEVICE FOR CIRCUIT BOARD AND ELECTROPLATING EQUIPMENT

(71) Applicant: UNIVERSAL CIRCUIT BOARD EQUIPMENT CO., LTD., Dongguan (CN)

(72) Inventor: Takwo CHAN, Dongguan (CN)

(73) Assignee: UNIVERSAL CIRCUIT BOARD EQUIPMENT CO., LTD., Dongguan (CN)

(21) Appl. No.: 19/026,131

(22) Filed: Jan. 16, 2025

(30) Foreign Application Priority Data
Nov. 4, 2024 (CN) 202411560899.2

(51) Int. Cl. H05K 3/24

(52) U.S. Cl. CPC H05K 3/241; H05K 2203/0195; H05K 2203/0723; H05K 2203/1509

(57) ABSTRACT

Disclosed are a feeding device for the circuit board and an electroplating equipment, which relates to the technical field of circuit board electroplating. The feeding device for the circuit board includes a frame and a feeding conveying mechanism, a positioning mechanism and a pushing mechanism provided at the frame. The feeding conveying mechanism is configured for horizontally placing the circuit board and conveying the circuit board to the electroplating conveying mechanism of the electroplating equipment in a horizontal direction. The positioning mechanism is configured to position the circuit board on the feeding conveying mechanism to a predetermined position. The pushing mechanism includes a first driving member and a first pushing member. The first pushing member is connected to the first driving member for driving the first pushing member to move back and forth in a first direction and drive the circuit board to move.

### CROSS-REFERENCE TO RELATED APPLICATIONS

This application claims priority to Chinese Patent Application No. 202411560899.2, filed on Nov. 4, 2024, the entire contents of which are incorporated herein by reference.

### TECHNICAL FIELD

The present application relates to the technical field of circuit board electroplating, and in particular to a feeding device for a circuit board and an electroplating equipment.

### BACKGROUND

In the current printed circuit board (PCB) manufacturing process, the effect of the first layer of electroplating often fails to meet the ideal standard, resulting in the need for second layer of electroplating. The ideal electroplating effect usually requires thin-layer electroplating first, followed by thick-layer electroplating. To achieve this goal, the existing electroplating method usually uses a horizontal electroplating machine.

Before the boards enter the electroplating machine, they are required to be arranged side by side and maintain a certain spacing. However, most equipment uses a roller conveyor structure, resulting in insufficient spacing control accuracy, usually only 10-15 mm. If the positioning is inaccurate, the plating thickness will cause tilt problems, which will affect the final electroplating quality and lead to low production efficiency.

### SUMMARY

The main purpose of this application is to propose a feeding device for a circuit board and electroplating equipment, aiming to solve the problem of low production efficiency of existing electroplating equipment.

To achieve the above purpose, the feeding device for the circuit board proposed in this application is applied to the electroplating equipment, includes: a frame; a feeding conveying mechanism; a positioning mechanism; and a pushing mechanism provided at the frame; the electroplating equipment includes an electroplating conveying mechanism and an electroplating cylinder, and the electroplating conveying mechanism is configured to drive the circuit board to move in the electroplating cylinder for electroplating; the feeding conveying mechanism is configured to place the circuit board horizontally and convey the circuit board to the electroplating conveying mechanism in a horizontal direction; the positioning mechanism is configured to position the circuit board on the feeding conveying mechanism to a preset position to make the circuit board move to the electroplating conveying mechanism in a first direction; and the pushing mechanism is configured to push the circuit board to move in the first direction to adjust a distance between two adjacent circuit boards positioned by the positioning mechanism and arranged along the first direction.

In one embodiment, the pushing mechanism includes a first driving member and a first pushing member, and the first pushing member is drivingly connected to the first driving member; the first pushing member has a first position and a second position on the first driving member; the positioning mechanism is located between the first position and the second position, and the first driving member is configured to drive the first pushing member to move back and forth between the first position and the second position.

In one embodiment, the first pushing member includes a first connecting plate and a first guide wheel; the first connecting plate is drivingly connected to the first driving member, and a plurality of the first guide wheels are rotatably provided at one side of the first connecting plate facing the feeding conveying mechanism and are provided at intervals along a second direction to push the circuit board to move.

In one embodiment, the first pushing member further includes a first lifting device; the first connecting plate is drivingly connected to the first driving member through the first lifting device, and the first lifting device is configured to drive the first connecting plate and the first guide wheel to move along a third direction to make the first guide wheel close to or away from the feeding conveying mechanism.

In one embodiment, the pushing mechanism is configured to push the circuit board positioned by the positioning mechanism to move along the first direction to make the distance between a pushed circuit board and a previous circuit board positioned by the positioning mechanism be a preset value L, and an actual distance value between the two circuit boards is D; L and D satisfy: D is greater than or equal to L−1.5 mm, and D is less than or equal to L+1.5 mm.

In one embodiment, the positioning mechanism includes a second driving member, a second pushing member and a positioning member; the positioning member is provided at one side of the feeding conveying mechanism, and the second pushing member is provided at the other side of the feeding conveying mechanism; a positioning area is formed between the second pushing member and the positioning member; the second pushing member is drivingly connected to the second driving member, and the second pushing member is configured to push the circuit board located in the positioning area to abut against the positioning member.

In one embodiment, the positioning member includes a mounting plate and a second guide wheel, and a plurality of the second guide wheels are rotatably provided at the mounting plate and provided at intervals along the first direction for abutting against the circuit board; and/or the second pushing member includes a second connecting plate and a third guide wheel; the second connecting plate is drivingly connected to the second driving member, and a plurality of the third guide wheels are rotatably provided at a side of the second connecting plate facing the feeding conveying mechanism and provided at intervals along the first direction for pushing the circuit board.

In one embodiment, the feeding conveying mechanism includes a plurality of rollers, and a plurality of the rollers are provided at intervals along the first direction to form a conveying line; a plurality of friction wheels are provided at intervals on each of the rollers, and the rollers are configured to drive the friction wheels to rotate to make the friction wheels drive the circuit board to move along the first direction.

In one embodiment, the feeding conveying mechanism further includes a steering support assembly provided at the positioning mechanism; the steering support assembly includes a bracket and a guide member, and a plurality of the guide members are movably provided at the bracket for slidingly abutting against the circuit board when the circuit board moves along the first direction or is positioned and moved by the positioning mechanism.

The present application further provides an electroplating equipment, including: an electroplating conveying mechanism; an electroplating cylinder; and the feeding device for the circuit board as described above.

The feeding device for the circuit board proposed in the technical solution of the present application adopts a positioning mechanism and a pushing mechanism to control the position and spacing of the circuit board on the feeding conveying mechanism to improve production efficiency. Specifically, the feeding device for the circuit board is configured to be provided at the board feeding end of the electroplating equipment. The electroplating equipment includes an electroplating conveying mechanism and an electroplating tank. The electroplating tank contains liquid chemical. The electroplating conveying mechanism is usually configured to clamp one side of the board edge of the circuit board and drive the circuit board to move in the electroplating tank to complete electroplating.

The feeding device for the circuit board includes a frame and a feeding conveying mechanism, a positioning mechanism and a pushing mechanism provided at the frame. The feeding conveying mechanism is a conveying line with a certain length. The feeding conveying mechanism is configured to place the circuit board horizontally and convey the circuit board to the electroplating conveying mechanism of the electroplating equipment in a horizontal direction. The positioning mechanism is configured to position the circuit board on the feeding conveying mechanism to a predetermined position so that the board edge of the circuit board is aligned with the electroplating conveying mechanism. After the positioning is completed, the circuit board moves to the electroplating conveying mechanism in a first direction. The pusher mechanism includes a first driving member and a first pushing member, the first pushing member is connected to the first driving member, and the first driving member is configured to drive the first pushing member to move back and forth along the first direction and drive the circuit board to move. During production, the operator generally puts multiple circuit boards on the feeding conveyor mechanism, and the first pushing member is configured to adjust the spacing between two adjacent circuit boards that are positioned and provided along the first direction.

As can be seen from the above, the circuit board is positioned by the positioning mechanism to align the electroplating conveyor mechanism to prevent the circuit board from being offset and tilted on the electroplating conveyor mechanism, thereby causing an unsatisfactory electroplating effect. In addition, the positioned circuit board is pushed to move by the pusher mechanism, so that the spacing between two adjacent circuit boards after positioning can be accurately controlled, thereby improving the uniformity of electroplating and production efficiency.

### BRIEF DESCRIPTION OF THE DRAWINGS

In order to more clearly illustrate the embodiments of the present application or the technical solutions in the related art, the drawings required for use in the embodiments or the description of the related art will be briefly introduced below. Obviously, the drawings described below are only some embodiments of the present application. For those skilled technical personel, other drawings can be obtained based on the structures shown in these drawings without creative work.

FIG. 1 is a schematic structural view of a feeding device for a circuit board according to an embodiment of the present application.

FIG. 2 is a schematic internal structural view of the feeding device for the circuit board according to an embodiment of the present application.

FIG. 3 is a schematic structural view of a feeding conveying mechanism, a positioning mechanism and a pushing mechanism in the feeding device for the circuit board according to an embodiment of the present application.

FIG. 4 is a top view of a feeding conveying mechanism and a positioning mechanism in the feeding device for the circuit board according to an embodiment of the present application.

FIG. 5 is a schematic structural view of a pushing mechanism in the feeding device for the circuit board according to an embodiment of the present application.

FIG. 6 is a schematic disassembled structural view of a first pushing member in the feeding device for the circuit board according to an embodiment of the present application.

FIG. 7 is a schematic structural view of an assembly structure of a positioning mechanism and a steering support assembly in the feeding device for the circuit board according to an embodiment of the present application.

FIG. 8 is a schematic disassembled structural view of a positioning mechanism and a steering support assembly in FIG. 7.

FIG. 9 is a schematic structural view of an electroplating equipment according to an embodiment of the present application.

FIG. 10 is a top view of the connection between the feeding device for the circuit board, an electroplating cylinder and an electroplating conveying mechanism in an electroplating equipment according to an embodiment of the present application.

The realization of the objective, functional characteristics, and advantages of the present application are further described with reference to the accompanying drawings.

### DETAILED DESCRIPTION OF THE EMBODIMENTS

The technical solutions of the embodiments of the present application will be described in more detail below with reference to the accompanying drawings. It is obvious that the embodiments to be described are only some rather than all of the embodiments of the present application. All other embodiments obtained by those skilled in the art based on the embodiments of the present application without creative efforts shall fall within the scope of the present application.

It should be noted that if there is a directional indication (such as up, down, left, right, front, rear) in the embodiments of the present application, the directional indication is only configured to explain the relative positional relationship, movement, etc. of the components in a certain posture (as shown in the drawings). If the specific posture changes, the directional indication will change accordingly.

Besides, the descriptions associated with, e.g., “first” and “second,” in the present application are merely for descriptive purposes, and cannot be understood as indicating or suggesting relative importance or impliedly indicating the number of the indicated technical feature. Therefore, the feature associated with “first” or “second” can expressly or impliedly include at least one such feature. The meaning of “and/or” appearing in the present application includes three parallel scenarios. For example, “A and/or B” includes only A, or only B, or both A and B. In addition, the technical solutions between the various embodiments can be combined with each other, but they must be based on the realization of those skilled in the art. When the combination of technical solutions is contradictory or cannot be achieved, it should be considered that such a combination of technical solutions does not exist, nor is it within the scope of the present application.

In the current printed circuit board (PCB) manufacturing process, the effect of one electroplating often fails to reach the ideal standard, resulting in the need for secondary electroplating. The ideal electroplating effect usually requires thin-layer electroplating first and then thick-layer electroplating. To achieve this goal, the existing electroplating method usually adopts a horizontal electroplating machine. Before the plate enters the electroplating machine, the board is required to be arranged side by side and maintain a certain spacing. However, the existing equipment uses a roller conveying structure, resulting in insufficient spacing control accuracy, which can usually only reach 10-15 mm. If the positioning is inaccurate, the tilt problem caused by the different thickness of the plate will affect the final electroplating quality and lead to low production efficiency.

The present application proposes a feeding device for a circuit board.

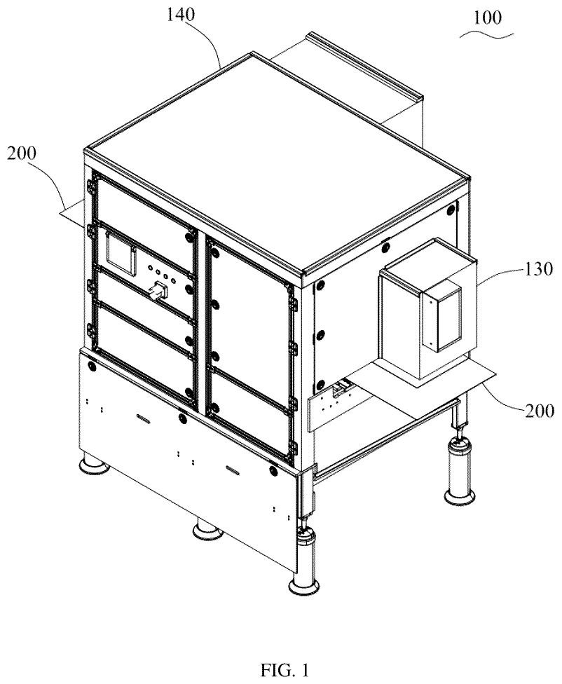

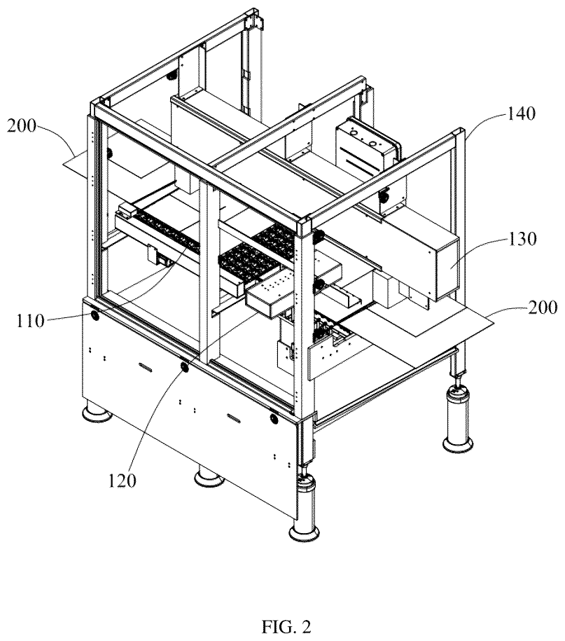

Please refer to FIG. 1 to FIG. 3. In one embodiment of the present application, the feeding device for the circuit board 100 is used to be arranged at the board feeding end of the electroplating equipment. The electroplating equipment includes an electroplating conveying mechanism and an electroplating tank. The electroplating tank contains a liquid. The electroplating conveying mechanism is usually used to clamp one side of the board edge of the circuit board 200 and drive the circuit board 200 to move in the electroplating tank to complete the electroplating.

The feeding device for the circuit board 100 includes a frame 140 and a feeding conveying mechanism 110, a positioning mechanism 120 and a pushing mechanism 130 arranged on the frame 140. The feeding conveying mechanism 110 is a conveying line with a certain length. The feeding conveying mechanism 110 is used to place the circuit board 200 horizontally and convey the circuit board 200 horizontally to the electroplating conveying mechanism of the electroplating equipment. The positioning mechanism 120 is used to position the circuit board 200 on the feeding conveying mechanism 110 to a predetermined position so that the board edge of the circuit board 200 is aligned with the electroplating conveying mechanism. After the positioning is completed, the circuit board 200 moves to the electroplating conveying mechanism along the first direction. The pushing mechanism 130 includes a first driving member 131 and a first pushing member 132. The first pushing member 132 is drivingly connected to the first driving member 131. The first driving member 131 is used to drive the first pushing member 132 to move back and forth along the first direction and drive the circuit board 200 to move. During production, the operator generally places multiple circuit boards 200 on the feeding conveying mechanism 110, and the first pushing member 132 is used to adjust the spacing between two adjacent circuit boards 200 that are positioned and arranged along the first direction.

As can be seen from the above, the circuit board 200 is positioned by the positioning mechanism 120 to align the electroplating conveying mechanism to prevent the circuit board 200 from being offset and tilted on the electroplating conveying mechanism, thereby causing an unsatisfactory electroplating effect. In addition, the positioned circuit board 200 is pushed to move by the pusher mechanism 130, so that the spacing between the two adjacent circuit boards 200 after positioning can be accurately controlled, thereby improving the uniformity of electroplating and production efficiency.

In one embodiment, the pusher mechanism 130 includes a first driving member 131 and a first pushing member 132. The first pushing member 132 is drivingly connected to the first driving member 131. The first pushing member 132 has a first position and a second position on the first driving member 131. The positioning mechanism 120 is located between the first position and the second position. The first driving member 131 is used to drive the first pushing member 132 to move back and forth between the first position and the second position.

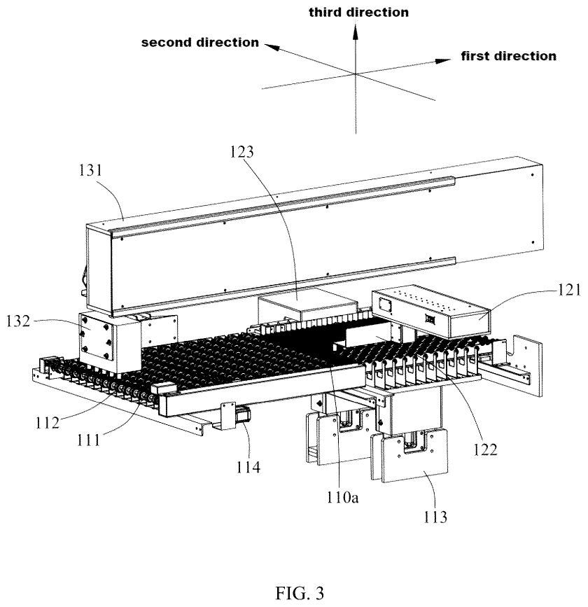

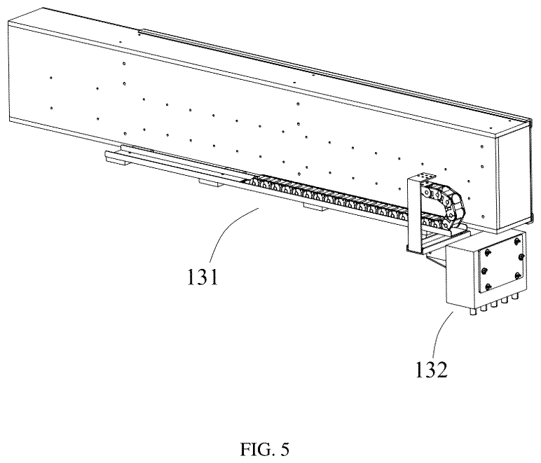

As shown in FIG. 3 and FIG. 5, in one embodiment of the present application, the first driving member 131 is a linear motor extending in a first direction. The first pushing member 132 is disposed below the first driving member 131, and the first pushing member 132 is at a first position and a second position at both ends of a maximum stroke on the first driving member 131, respectively. The positioning mechanism 120 is disposed between the first position and the second position. In a further embodiment, the position of the first pushing member 132 in FIG. 3 is the first position. At this time, when the operator places multiple circuit boards 200 horizontally on the feeding conveying mechanism 110 in sequence, the multiple circuit boards 200 enter the operating range of the first pushing member 132 at intervals, and whenever a circuit board 200 enters the operating range. When the circuit board 200 is moved to the second position, the first pushing member 132 moves to the second position and pushes the circuit board 200 to the positioning mechanism 120 and stops. After the positioning mechanism 120 positions the circuit board 200 to the preset position, the first pushing member 132 continues to move to the second position to push the circuit board 200. There is also a transition section (not shown) between the feeding conveying mechanism 110 and the electroplating conveying mechanism shown in the figure. The first pushing member 132 pushes the positioned circuit board 200 onto the transition section and keeps a certain distance from the previous circuit board 200. Then the first pushing member 132 returns to the first position and circulates the pushing operation. The multiple circuit boards 200 on the transition section enter the electroplating conveying mechanism in sequence along the first direction.

In order to ensure the spacing of the circuit boards 200 entering the electroplating conveying mechanism, the running speeds of the transition section and the electroplating conveying mechanism are usually adjusted to be consistent. If factors such as sliding friction are considered, the transportation speed of the transition section can be slightly faster than that of the electroplating conveying mechanism, which can be adjusted according to actual conditions. When the specifications of the circuit boards 200 are consistent, when the first pushing member 132 pushes the circuit board 200 to the positioning mechanism 120, the position of the current circuit board 200 on the feeding conveying mechanism 110 is determined. The time from the first pushing member 132 pushing the current circuit board 200 into the positioning mechanism 120, and the positioning mechanism 120 completing the positioning and then pushing it to the transition section is fixed. The previous circuit board 200 moves at the first speed on the transition section. It is only necessary to determine the moving distance of the previous circuit board 200 within the time difference, and adjust the speed and distance of the first pushing member 132 moving from the first position to the second position to accurately control the spacing between the current circuit board 200 and the previous circuit board 200, so as to improve the electroplating quality of the circuit board 200.

Of course, in some other embodiments of the present application, the positions of the positioning mechanism 120 and the first pushing member 132 are not specifically limited. For example, the positioning mechanism 120 can be set at the first position or at the side of the first position away from the second position, as long as the spacing of the circuit board 200 entering the electroplating conveying mechanism can be accurately controlled. In addition, the first driving member 131 and the first pushing member 132 can also be set below the feeding conveying mechanism 110, so that the first pushing member 132 can pass through the feeding conveying mechanism 110 and abut the circuit board 200. At this time, the feeding conveying mechanism 110 can be provided with an avoidance groove for the first pushing member 132 to push the circuit board to move along the first direction. The specific setting can be based on actual needs and is not specifically limited here.

In one embodiment, the first pushing member 132 includes a first connecting plate 1321 and a first guide wheel 1322. The first connecting plate 1321 is drivingly connected to the first driving member 131. A plurality of first guide wheels 1322 are rotatably disposed on one side of the first connecting plate 1321 toward the feeding conveying mechanism 110 and are arranged at intervals along the second direction to push the circuit board 200 to move.

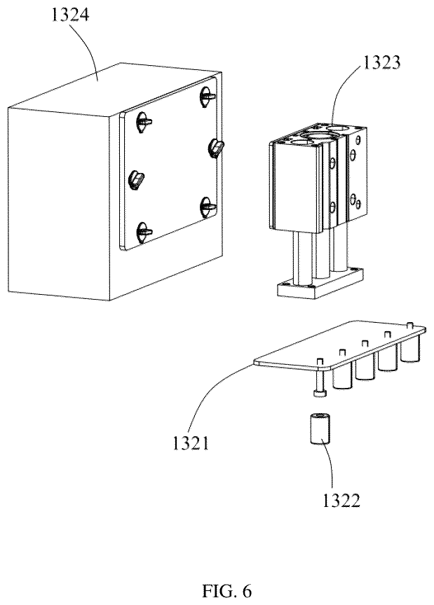

As shown in FIG. 3, FIG. 5 and FIG. 6, in one embodiment of the present application, the first pushing member 132 includes a first connecting plate 1321 and a first guide wheel 1322. The first connecting plate 1321 is drivingly connected to the first driving member 131. There are multiple first guide wheels 1322. The first connecting plate 1321 is provided with multiple rotating shafts at intervals on one side facing the feeding conveying mechanism 110. Each rotating shaft is rotatably provided with a first guide wheel 1322. The multiple first guide wheels 1322 are arranged at intervals along the second direction, which is the width direction of the feeding conveying mechanism 110. The surface of the first guide wheel 1322 is used to abut against the side edge of the circuit board 200 to push the circuit board 200 to move along the first direction. When the circuit board 200 is positioned, it may move along the second direction. At this time, the board edge slides against the multiple first guide wheels 1322 to reduce wear.

In one embodiment, the first pushing member 132 also includes a first lifting device 1323, and the first connecting plate 1321 is driven and connected to the first driving member 131 through the first lifting device 1323. The first lifting device 1323 is used to drive the first connecting plate 1321 and the first guide wheel 1322 to move along the third direction so that the first guide wheel 1322 is close to or away from the feeding conveying mechanism 110.

As shown in FIG. 3, FIG. 5 and FIG. 6, in one embodiment of the present application, the first pushing member 132 also includes a first lifting device 1323 and a box body 1324. Specifically, the box body 1324 is connected to the first driving member 131 through a connecting member. The first lifting device 1323 is a cylinder arranged in the box body 1324. The first connecting plate 1321 is fixed on the first lifting device 1323. The first lifting device 1323 is used to drive the first connecting plate 1321 and the multiple first guide wheels 1322 on the first connecting plate 1321 to move along the third direction, so that the first guide wheel 1322 moves toward or away from the feeding conveying mechanism 110. Specifically, when the circuit board 200 moves toward the positioning mechanism 120 on the feeding conveying mechanism 110, the first lifting device 1323 drives the first guide wheel 1322 to rise in order to avoid blocking the circuit board 200. When the circuit board 200 completely enters the operating range of the first pushing member 132, the first lifting device 1323 drives the first guide wheel 1322 to descend so that the side wall of the first guide wheel 1322 can abut against the side of the circuit board 200. At this time, the first driving member 131 drives the first pushing member 132 to move to push the circuit board 200.

In one embodiment, the pusher mechanism 130 is used to push the circuit board 200 positioned by the positioning mechanism 120 to move along the first direction, so that the distance between the pushed circuit board 200 and the previous circuit board 200 positioned by the positioning mechanism 120 is a preset value L. The actual distance value of the two circuit boards is D, and L and D satisfy: D is greater than or equal to L−1.5 mm, and D is less than or equal to L+1.5 mm.

Since multiple circuit boards 200 need to enter the electroplating cylinder in sequence, the uneven spacing of the circuit boards 200 may cause uneven flow of the electroplating solution, resulting in excessively thick or thin coating in some areas, affecting the overall performance. The existing equipment uses a roller conveying structure, and the spacing control accuracy is not high. As shown in FIG. 3, in one embodiment of the present application, the pushing mechanism 130 uses a linear motor, and uses a first pushing member 132 to push the circuit board 200 positioned by the positioning mechanism 120 to the electroplating conveying mechanism to catch up with the previous circuit board 200. The operating gap and transportation distance are calculated by the controller, and the positioning mechanism 120 and the pushing mechanism 130 are controlled to cooperate with each other so that the spacing value between two adjacent circuit boards 200 is controlled within a preset value L, for example, the preset value L of the plate spacing can be set to 5 mm, 10 mm or 15 mm, etc., but due to the influence of the control accuracy of the mechanical equipment, the actual spacing value D is different from the preset value L. By controlling the linear motor, the error between the spacing value D and the preset value L can be further reduced compared to conventional roller conveying. Specifically, L and D satisfy: L−1.5 mm≤D≤L+1.5 mm, that is, the error can be controlled within the range of 1.5 mm. For example, the preset value L between the plates is set to 10 mm, then the minimum value of the actual spacing value D can be 8.5 mm, and the maximum value can be 11.5 mm. The spacing value D can also be 9.5 mm, or any value within the aforementioned range. Compared with the traditional roller conveying structure, the control is more precise, and the electroplating effect is better.

In one embodiment, the positioning mechanism 120 includes a second driving member 121, a second pushing member 122 and a positioning member 123. The positioning member 123 and the second pushing member 122 are respectively arranged on both sides of the feeding and conveying mechanism 110. A positioning area 110a is formed between the second pushing member 122 and the positioning member 123. The second pushing member 122 is drivingly connected to the second driving member 121. The second pushing member 122 is used to push the circuit board 200 located in the positioning area 110a to abut against the positioning member 123.

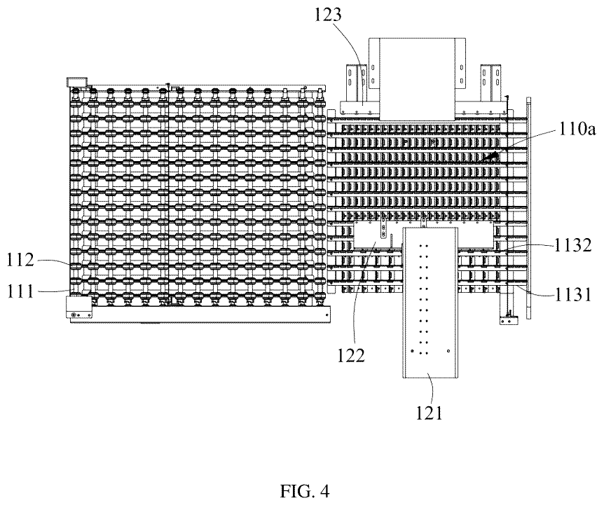

As shown in FIG. 3 and FIG. 4, in one embodiment of the present application, the positioning mechanism 120 includes a second driving member 121, a second pushing member 122 and a positioning member 123. Specifically, the positioning member 123 and the second pushing member 122 are respectively arranged on opposite sides of the feeding conveying mechanism 110, and a positioning area 110a is formed between the two. The second pushing member 122 and the second driving member 121 are drivingly connected. When the first pushing member 132 pushes the circuit board 200 to the positioning area 110a along the first direction, the second driving member 121 The second pushing member 122 is driven to push the circuit board 200 along the second direction so that its side abuts against the positioning member 123. It should be noted that the angle formed by the first direction and the second direction can be 90° or other angles. The abutting position of the positioning member 123 is consistent with the clamping position of the electroplating conveying mechanism. The side of the circuit board 200 abuts against the positioning member 123 to align with the electroplating conveying mechanism. After the alignment is completed, the first pushing member 132 pushes the current circuit board 200 away from the positioning area 110a to catch up with the previous circuit board 200. In this embodiment, the second driving member 121 also adopts a linear motor. The second driving member 121 is arranged on the frame 140 along the second direction. It can be understood that due to the inconsistent size specifications of different circuit boards 200, the second pushing member 122 and the positioning member 123 are provided to push circuit boards 200 of different specifications along the second direction until they abut against the positioning member 123 to complete the positioning.

In one embodiment, the positioning member 123 includes a mounting plate 1231 and a second guide wheel 1232, and a plurality of second guide wheels 1232 are rotatably disposed on the mounting plate 1231 and arranged at intervals along the first direction for contacting the circuit board 200.

In one embodiment, the second pushing member 122 includes a second connecting plate 1221 and a third guide wheel 1222, and the second connecting plate 1221 is drivingly connected to the second driving member 121. A plurality of third guide wheels 1222 are rotatably disposed on a side of the second connecting plate 1221 facing the feeding conveying mechanism 110 and arranged at intervals along the first direction for pushing the circuit board 200.

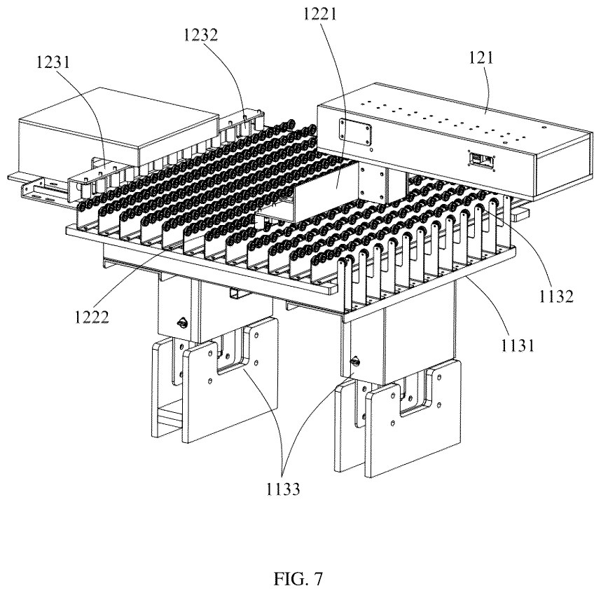

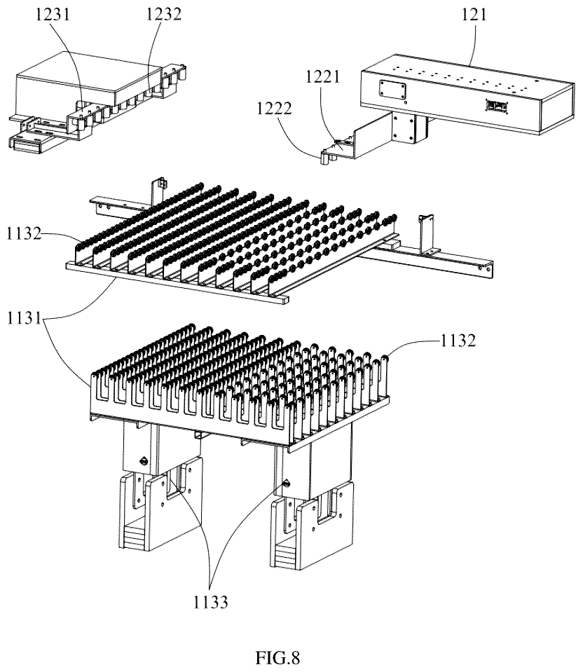

As shown in FIG. 7 and FIG. 8, in one embodiment of the present application, the positioning member 123 includes a mounting plate 1231 and a second guide wheel 1232, and the second pushing member 122 includes a second connecting plate 1221 and a third guide wheel 1222. Specifically, the mounting plate 1231 extends along the first direction and is arranged on one side of the feeding conveying mechanism 110, and a plurality of rotatable second guide wheels 1232 are arranged on the mounting plate 1231 at intervals along the first direction; and the second connecting plate 1221 also extends along the first direction and is provided with a plurality of rotatable third guide wheels 1222 at intervals. When the circuit board 200 enters the positioning area 110a, the second connecting plate 1221 to move toward the positioning member 123, and the plurality of third guide wheels 1222 abut against the side edge of the circuit board 200 parallel to the first direction and push it toward the positioning member 123. The side of the circuit board 200 parallel to the second direction slides against the first guide wheel 1322, and the side of the circuit board 200 away from the third guide wheel 1222 abuts against the plurality of second guide wheels 1232 to complete positioning. At this time, the first pushing member 132 pushes the circuit board 200 along the first direction, and the two sides of the circuit board 200 parallel to the first direction slide against the second guide wheel 1232 and the third guide wheel 1222, respectively, which can reduce wear and extend the life of the equipment.

In one embodiment, the feeding conveying mechanism 110 includes a plurality of rollers 111, which are arranged at intervals along the first direction to form a conveying line, and each roller 111 is provided with a plurality of friction wheels 112 at intervals, and the roller 111 is used to drive the friction wheel 112 to rotate, so that the friction wheel 112 drives the circuit board 200 to move along the first direction.

As shown in FIG. 3 and FIG. 4, in one embodiment of the present application, the feeding conveying mechanism 110 includes a plurality of rollers 111. Specifically, the plurality of rollers 111 are arranged side by side on the frame 140 along a first direction to form a conveyor line. A plurality of friction wheels 112 are arranged on each roller 111. The frame 140 is also provided with a driving motor 114. The ends of any two adjacent rollers 111 are provided with meshing gears. The driving motor 114 drives the plurality of rollers 111 to rotate at the same speed through the gears. The friction wheels 112 are in contact with the bottom of the board surface to drive the circuit board 200 to move. The position where the friction wheels 112 contacting the circuit board 200 can adopt a structure such as soft rubber to prevent scratches. The friction wheels 112 are arranged at intervals to form an avoidance space for the first guide wheel 1322 to rise and fall and move to avoid interference.

In one embodiment, the feeding conveying mechanism 110 further includes a steering support assembly 113 disposed at the positioning mechanism 120. The steering support assembly 113 includes a bracket 1131 and a guide 1132, and a plurality of guides 1132 are movably disposed on the bracket 1131, and are used to slide and abut against the circuit board 200 when the circuit board 200 moves along the first direction or is positioned and moved by the positioning mechanism 120.

As shown in FIG. 3, FIG. 7 and FIG. 8, in one embodiment of the present application, the feeding conveying mechanism 110 further includes a steering support assembly 113 disposed in the positioning area 110a. The steering support assembly 113 includes two brackets 1131 and a plurality of guides 1132 disposed on the two brackets 1131, the guides 1132 are rollers The rollers on one of the brackets 1131 are rotatably disposed along the first direction, the rollers on the other bracket 1131 are rotatably disposed along the second direction. One of the two brackets 1131 is rotatably disposed along the second lifting and lowering portion 1132 on the frame 140. The first pushing member 132 is connected to the circuit board 200 and the second lifting device 1133. When the first pushing member 132 pushes the circuit board 200 to the positioning area 110a, the bottom surface of the circuit board 200 slides and abuts against the guide member 1132 rotatably arranged along the first direction. When entering the positioning operation, the second lifting device 1133 drives the bracket 1131 connected to itself to rise and fall, so that the guide member 1132 rotatably arranged along the second direction abuts against the bottom surface of the circuit board 200. When the second pushing member 122 pushes the circuit board 200 to move toward the positioning member 123, the bottom surface of the circuit board 200 slides and abuts against the roller rotatably arranged along the second direction. As can be seen from the above, by setting the steering support assembly 113, scratches on the circuit board 200 when it moves or is positioned on the feeding conveying mechanism 110 are avoided, and the product quality of the circuit board 200 is guaranteed.

In another embodiment of the present application, the steering support assembly 113 may use a bracket 1131, and the guide member 1132 may use a universal ball or a universal bead. Multiple universal balls or universal beads are set on the bracket 1131 to abut against the circuit board 200. When the circuit board 200 enters the positioning area 110a and moves, the universal ball or universal bead rotates with the circuit board 200, which can also avoid scraping. Therefore, the specific structure of the bracket 1131 and the guide member 1132 in this solution is not limited.

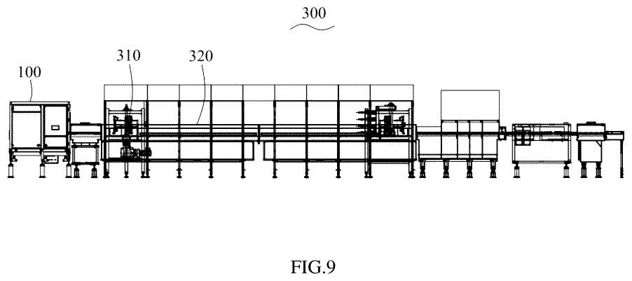

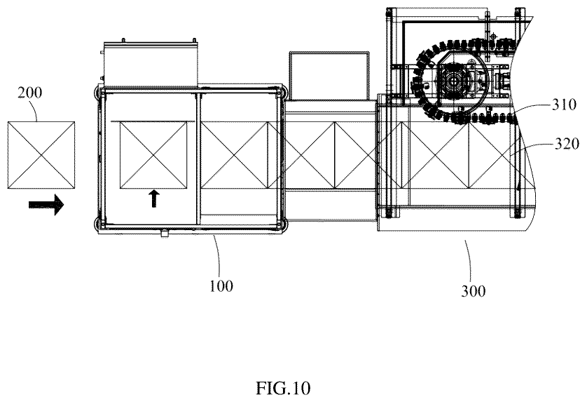

The present application also proposes an electroplating equipment 300, which includes an electroplating conveying mechanism 310, an electroplating tank 320, and a feeding device for the circuit board 100. As shown in FIG. 9 and FIG. 10, the electroplating conveying mechanism 310 is disposed in the electroplating tank 320, and the electroplating conveying mechanism 310 is docked with the feeding conveying mechanism 110 of the feeding device for the circuit board 100. The circuit board 200 moves from the feeding conveying mechanism 110 to the electroplating conveying mechanism 310, and then is clamped by the electroplating conveying mechanism 310 and horizontally moved in the electroplating tank 320 for electroplating. The specific structure of the feeding device for the circuit board 100 refers to the above embodiment. Since the present electroplating device adopts all the technical solutions of all the above embodiments, it has at least all the beneficial effects brought by the technical solutions of the above embodiments, which will not be repeated here.

The above contents are only some embodiments of the present application, and do not limit the scope of the present application. All equivalent structural changes made by using the contents of the present application specification and drawings under the inventive concept of the present application, or directly/indirectly applied in other related technical fields are included in the scope of the present application.

What is claimed is:

1. A feeding device for a circuit board, applied to an electroplating equipment, comprising:
a frame;
a feeding conveying mechanism;
a positioning mechanism; and
a pushing mechanism provided at the frame;
wherein the electroplating equipment comprises an electroplating conveying mechanism and an electroplating tank, and the electroplating conveying mechanism is configured to drive the circuit board to move in the electroplating tank for electroplating;
the feeding conveying mechanism is configured to place the circuit board horizontally and convey the circuit board to the electroplating conveying mechanism in a horizontal direction;
the positioning mechanism is configured to position the circuit board on the feeding conveying mechanism to a preset position to make the circuit board move to the electroplating conveying mechanism in a first direction; and
the pushing mechanism is configured to push the circuit board to move in the first direction to adjust a distance between two adjacent circuit boards positioned by the positioning mechanism and arranged along the first direction.

2. The feeding device for the circuit board according to claim 1, wherein the pushing mechanism comprises a first driving member and a first pushing member, and the first pushing member is drivingly connected to the first driving member; the first pushing member has a first position and a second position on the first driving member; the positioning mechanism is located between the first position and the second position, and the first driving member is configured to drive the first pushing member to move back and forth between the first position and the second position.

3. The feeding device for the circuit board according to claim 2, wherein the first pushing member comprises a first connecting plate and a first guide wheel; the first connecting plate is drivingly connected to the first driving member, and a plurality of the first guide wheels are rotatably provided at one side of the first connecting plate facing the feeding conveying mechanism and are provided at intervals along a second direction to push the circuit board to move.

4. The feeding device for the circuit board according to claim 3, wherein the first pushing member further comprises a first lifting device; the first connecting plate is drivingly connected to the first driving member through the first lifting device, and the first lifting device is configured to drive the first connecting plate and the first guide wheel to move along a third direction to make the first guide wheel close to or away from the feeding conveying mechanism.

5. The feeding device for the circuit board according to claim 1, wherein the pushing mechanism is configured to push the circuit board positioned by the positioning mechanism to move along the first direction to make the distance between a pushed circuit board and a previous circuit board positioned by the positioning mechanism be a preset value L, and an actual distance value between the two circuit boards is D; L and D satisfy: D is greater than or equal to L−1.5 mm, and D is less than or equal to L+1.5 mm.

6. The feeding device for the circuit board according to claim 1, wherein the positioning mechanism comprises a second driving member, a second pushing member and a positioning member; the positioning member is provided at one side of the feeding conveying mechanism, and the second pushing member is provided at the other side of the feeding conveying mechanism; a positioning area is formed between the second pushing member and the positioning member; the second pushing member is drivingly connected to the second driving member, and the second pushing member is configured to push the circuit board located in the positioning area to abut against the positioning member.

7. The feeding device for the circuit board according to claim 6, wherein the positioning member comprises a mounting plate and a second guide wheel, and a plurality of the second guide wheels are rotatably provided at the mounting plate and provided at intervals along the first direction for abutting against the circuit board; and/or
the second pushing member comprises a second connecting plate and a third guide wheel; the second connecting plate is drivingly connected to the second driving member, and a plurality of the third guide wheels are rotatably provided at a side of the second connecting plate facing the feeding conveying mechanism and provided at intervals along the first direction for pushing the circuit board.

8. The feeding device for the circuit board according to claim 1, wherein the feeding conveying mechanism comprises a plurality of rollers, and a plurality of the rollers are provided at intervals along the first direction to form a conveying line; a plurality of friction wheels are provided at intervals on each of the rollers, and the rollers are configured to drive the friction wheels to rotate to make the friction wheels drive the circuit board to move along the first direction.

9. The feeding device for the circuit board according to claim 1, wherein the feeding conveying mechanism further comprises a steering support assembly provided at the positioning mechanism; the steering support assembly comprises a bracket and a guide member, and a plurality of the guide members are movably provided at the bracket for slidingly abutting against the circuit board when the circuit board moves along the first direction or is positioned and moved by the positioning mechanism.

10. An electroplating equipment, comprising:
an electroplating conveying mechanism;
an electroplating tank; and
the feeding device for the circuit board according to claim 1.
